(19) United States
(12) Patent Application Publication
(10) Pub. No.: US 2008/0093110 A1
(43) Pub. Date: Apr. 24, 2008

(54) Rigid/Flexible Circuit Board

(75) Inventor: Detlev Bagung, Bernhardswald (DE)

Correspondence Address: LERNER GREENBERG STEMER LLP, P O BOX 2480, HOLLYWOOD, FL, 33022-2480, US

(73) Assignee: Siemens VDO Automotive Aktiengesellschaft, Munchen (DE)

(21) Appl. No.: 11/908,809

(22) PCT Filed: Jan. 18, 2006
(86) PCT No.: PCT/EP06/50266

§ 371 Date: Sep. 17, 2007

(30) Foreign Application Priority Data
Mar. 17, 2005 (DE) 10 2005 012 404.6

(51) Int. Cl. H05K 1/00

(52) U.S. Cl. 174/254

(57) ABSTRACT

A printed circuit board has a first elongated face and a second elongated face opposite the first face. The printed circuit board has at least one first, second and third rigid region in addition to at least one first and second flexible region. The flexible regions are perpendicular to the faces and are thinner than the rigid regions. The first rigid region is only coupled to the second rigid region by way of the first flexible region and the second rigid region is only coupled to the third rigid region by way of the second flexible region. The first flexible region lies flush against the first face and the second flexible region lies flush against the second face of the printed circuit board.

The invention relates to a circuit board which comprises at least one first, one second and one third rigid region and at least one first and one second flexible region.

A circuit board often has to be adapted in respect of its embodiment to external peripheral conditions. A motor vehicle can for example be constructed according to aspects such as aesthetics, aerodynamics and safety. The volume of space available for installing the circuit board in the motor vehicle can be subordinate to these considerations. The embodiment and arrangement of the circuit board must then be adapted to the available space.

The object of the invention is to create a circuit board simplifies arranging the circuit board in a variety of ways. The object is achieved by the features of the independent claim. Advantageous embodiments of the invention are identified in the subclaims.

The outstanding feature of the invention is a circuit board which features a first elongated face and a second elongated face opposite the first face. The circuit board comprises at least one first, one second and one third rigid region and at least one first and one second flexible region. The flexible regions are embodied perpendicular to the faces of the circuit board and are thinner than the rigid regions. The first rigid region is only coupled to the second rigid region by means of the first flexible region. The second rigid region is only coupled to the third rigid region by means of the second flexible region. The first flexible region lies flush against the first face of the circuit board. The second flexible region lies flush against the second face of the circuit board.

This makes it possible for the first rigid region to be bent in different direction in relation to the second rigid region from the direction in which the second rigid region is bent in relation to the third rigid region. Furthermore the flexible regions can be embodied simply and very precisely by depth milling of the circuit board.

In an advantageous embodiment the circuit board comprises more than two flexible regions and more than three rigid regions. The circuit board can then be easily adapted to a predetermined volume of space available for it.

In a further advantageous embodiment of the circuit board the two flexible regions are embodied so that a first transition from a first flexible region to the second rigid region and a second transition from the second rigid region to the second flexible region encloses an angle which is not equal to 0°.

This affords two further degrees of freedom in the embodiment of the flexible regions. Mounting the circuit board is than a simple matter.

Exemplary embodiments of the invention are explained in greater detail below with reference to the schematic drawings. The figures show:

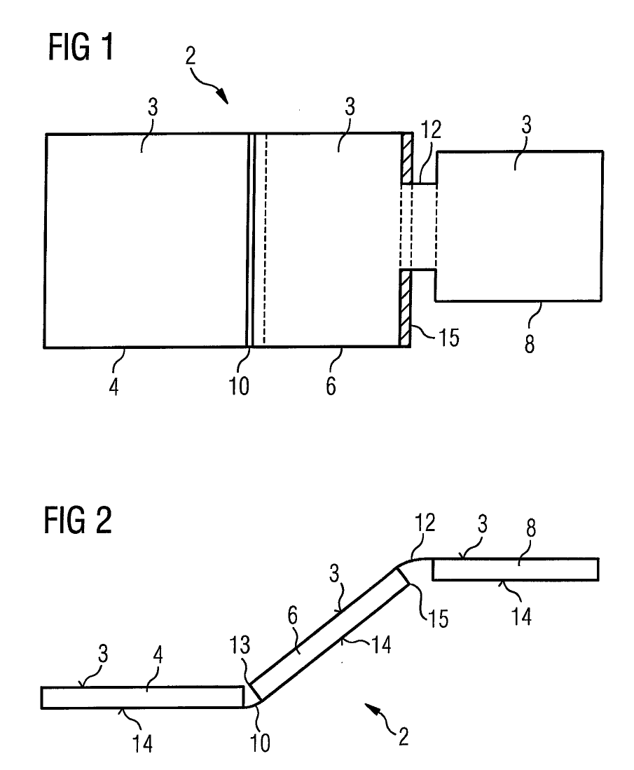

FIG. 1 an overhead view of a first embodiment of a circuit board,

FIG. 2 a side view of the circuit board in accordance with FIG. 1,

FIG. 3 an overhead view of a second embodiment of the circuit board,

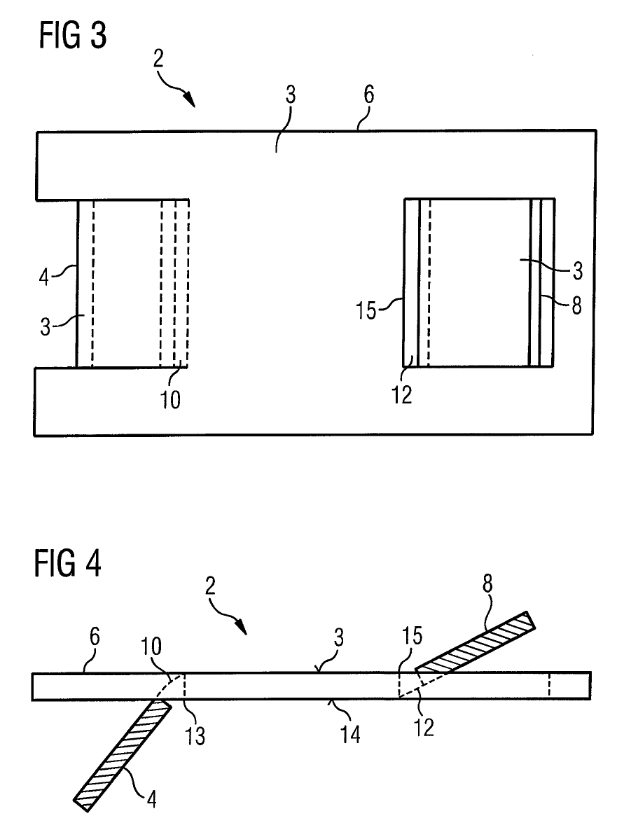

FIG. 4 a side view of the circuit board in accordance with FIG. 3,

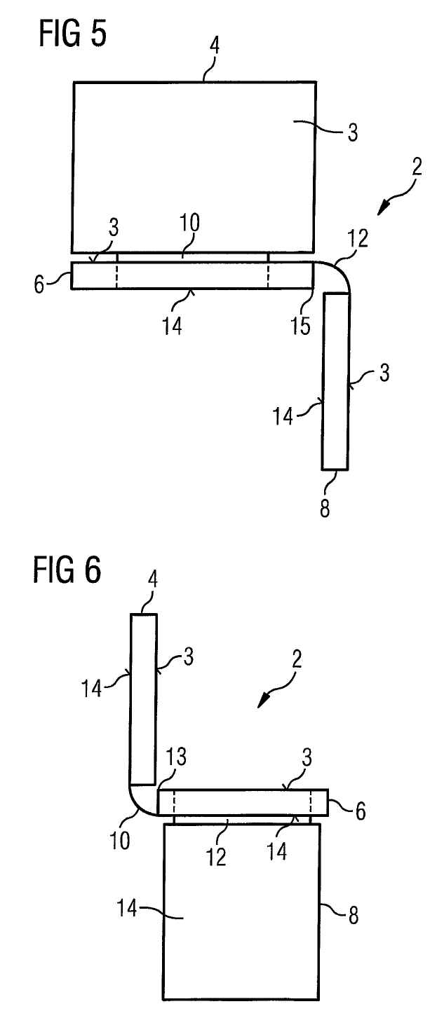

FIG. 5 a third embodiment of the circuit board,

FIG. 6 a side view of the circuit board in accordance with FIG. 5,

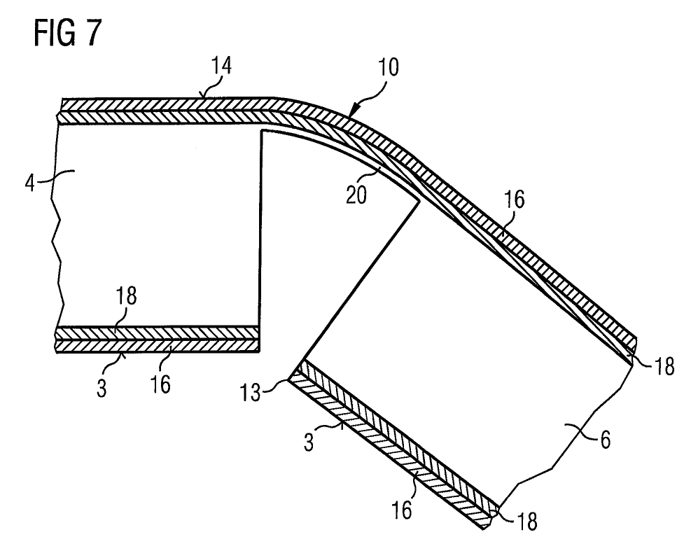

FIG. 7 a detailed side view of the circuit board.

Elements which are constructed or which function in the same way are identified by the same reference symbol in all figures.

A circuit board 2 (FIG. 1) comprises a first elongated face 3. The circuit board 2 is subdivided into a first rigid region 4, a second rigid region 6 and a third rigid region 8. A first flexible region 10 couples the first rigid region 4 to the second rigid region. A second flexible region 12 couples the second rigid region 6 to the third rigid region. A first edge 13 is embodied at a first transition from the first flexible region 10 to the second rigid region 6. A second edge 15 is embodied at the second transition from the second rigid region 12 to the second flexible region 12. The first flexible region 10 extends across the entire width of the circuit board. The first flexible region 10 can however also only extend over a part of the width of the circuit board 2 and/or extend from an outer edge of the circuit board 2 to another outer edge of the circuit board 2. The first rigid region 4 is embodied to lie flush with a second elongated face 14 of the circuit board 2 (FIG. 2). The first rigid region 4 and the second rigid region 6 can deviate from each other as regards their length and width. The second flexible region 12 only extends over a part of the width of the circuit board 2. The second flexible region 12 can also extend to the entire width of the circuit board 2 and/or extend from an outer edge of the circuit board 2 to another outer edge of the circuit board 2. The second flexible region 12 is embodied flush with the face 3 of the circuit board 2. The third rigid region 8 has a smaller width than the two rigid regions 4, 6. It can however also be the same width as the first rigid region and/or the second rigid region 6.

The first rigid region 4 is bent in relation to the second rigid region 6 at the first flexible region 10 in the clockwise direction (FIG. 2). The second rigid region 6 is bent in relation to the third rigid region 8 at the second flexible region 12 in the counterclockwise direction. The third rigid region 8 is embodied thicker than the first rigid region 4 and the second rigid region 6. The third rigid region can also be embodied to be the same thickness as the first rigid region 4 and/or the second rigid region 6.

The first rigid region 4 and/or the third rigid region 8 can be embodied so that they are surrounded partly or entirely by the second rigid region 6 before being bent (FIG. 3, FIG. 4).

The first edge 13 and the second edge 15 can be embodied so that they make an angle in the projection onto a plane which is not equal to 0° (FIG. 5, FIG. 6).

During manufacturing the second face 14 of the circuit board 2 is laid on a support surface. Then the circuit board 2 is aligned and fixed on the support surface. Subsequently the circuit board 2 is depth milled perpendicular to the support surface in the first flexible region 10 to a predetermined first thickness. Thereafter the first flexible region 10 can merely comprise a layer 18 for conductor tracks and a protective layer 16 for the conductor tracks (FIG. 7), which are made of copper for example. The protective layer 16 can for example comprise a protective lacquer. In addition to the protective layer 16 and the layer 18 for conductor tracks, a residual layer 20 can also be embodied, which is preferably formed from the same material as the circuit board 2 and preferably is embodied on the side of the layer 18 for conductor tracks which faces away from the protective layer 16. The material of circuit board 2 preferably comprises FR4. The residual layer 20 can also be made of a different material from the circuit board 2. Depending on the use of the circuit board 2, the layer 18 for conductor tracks, the protective layer 16 and/or the residual layer 20 can then be embodied with a different material strength. The circuit board 2 is then cleaned. After cleaning the circuit board 2 is turned over and laid with the first face 3 on the support surface. The circuit board 2 is again aligned on the support surface and fixed. The fixing can for example be achieved by holding the circuit board 2 on the support surface by suction. Then the circuit board 2 is depth milled perpendicular to the support surface in the second flexible region 12 to a predetermined second thickness.

Alternately the circuit board 2 is laid on its second face on the support surface during manufacturing 14. Then the circuit board 2 is aligned and fixed on the support surface. A cutout is embodied in the support surface in the area of the second flexible region 12. The circuit board 2 is depth milled perpendicular to the support surface in the first flexible region 10 to a predetermined first thickness. Subsequently the circuit board 2 is pressed with a press onto the support surface. The circuit board 2 can also be held by suction on the support surface through openings in the support surface. Then the circuit board 2 is depth milled perpendicular to the support surface through the recess in the support surface in the second flexible region 12 to a predetermined second thickness.

1-3. (canceled)

4. A circuit board, comprising:
a first face and second face opposite the first face,
at least one first rigid region, at least one second rigid region, and at least one third rigid region;
at least one first flexible region and at least one second flexible region, said first and second flexible regions having a lesser thickness than said rigid regions in a direction perpendicular to said first and second faces;
said first rigid region being coupled to said second rigid region only by way of said first flexible region, and said second rigid region being coupled to said third rigid region only by way of said second flexible region; and
said first flexible region being flush with said first face of the circuit board and said second flexible region being flush with said second face of the circuit board.

5. The circuit board according to claim 4, which comprises more than two flexible regions and more than three rigid regions.

6. The circuit board according to claim 4, wherein said two flexible regions are formed such that a first edge makes an angle at a first transition from said first flexible region to said second rigid region and a second edge at a second transition from the second rigid region to the second flexible region which is not equal to 0°.
